(19) United States
(12) Patent Application Publication
(10) Pub. No.: US 2016/0233017 A1
(43) Pub. Date: Aug. 11, 2016

(54) INDUCTOR ARRAY CHIP AND DC-TO-DC CONVERTER MODULE USING THE SAME

(71) Applicant: Murata Manufacturing Co., Ltd., Kyoto (JP)

(72) Inventor: Motonori Murase, Kyoto (JP)

(21) Appl. No.: 15/132,888

(22) Filed: Apr. 19, 2016

Related U.S. Application Data
(63) Continuation of application No. PCT/JP2014/077050, filed on Oct. 9, 2014.

(30) Foreign Application Priority Data
Oct. 29, 2013 (JP) 2013-223822

(51) Int. Cl. H01F 27/28; G05F 3/08; H01F 27/245

(52) U.S. Cl. CPC H01F 27/2804; H01F 27/245; G05F 3/08; H01F 2027/2809

(57) ABSTRACT

Coil conductor patterns CP31 to CP34 and CP41 to CP44 are formed to be close to an outermost layer of a multilayer body. The coil conductor patterns CP31 and CP41 are connected by via hole conductors VH111b and VH111c, the coil conductor patterns CP32 and CP42 are connected by via hole conductors VH112b and VH112c, the coil conductor patterns CP33 and CP43 are connected by via hole conductors VH113b and VH113c, and the coil conductor patterns CP34 and CP44 are connected by via hole conductors VH114b and VH114c. Coil conductor patterns CP101 to CP104 and CP111 to CP114 formed to be close to the other outermost layer of the multilayer body are also connected in the same manner.

### FIELD OF THE DISCLOSURE

The present disclosure relates to an inductor array chip, and in particular, relates to an inductor array chip including a multilayer body formed by laminating a plurality of ceramic sheets at least some of which have magnetism and a plurality of inductors provided in the multilayer body and having a plurality of inductance values at least one of which is different from other inductance values.

The disclosure also relates to a DC-to-DC converter module, and in particular, relates to a DC-to-DC converter module including a multilayer body formed by laminating a plurality of ceramic sheets at least some of which have magnetism, a plurality of inductors provided in the multilayer body and having a plurality of inductance values at least one of which is different from other inductance values, and a switching integrated circuit (IC) mounted on the multilayer body and connected to the plurality of inductors.

### DESCRIPTION OF THE RELATED ART

A multi-channel DC-to-DC converter in which a plurality of inductors are provided in a single multilayer body and a switching IC is mounted on a top surface of the multilayer body and that outputs a plurality of direct-current (DC) voltages, which are different from one another, at the same time has been known. In the multi-channel DC-to-DC converter, specifications of output voltages and/or output currents (load currents) are different from channel to channel. Therefore, different inductance values are also required for the inductors provided in the multilayer body.
Patent Document 1: International Publication No. 2012/169242

### BRIEF SUMMARY OF THE DISCLOSURE

In order to make inductance values different among channels, wiring widths and the numbers of coil conductor patterns formed on respective laminated ceramic sheets are required to be changed among the channels. It should be noted that the change causes the deterioration in the flatness of the multilayer body undesirably.

Further, magnetic lines generated on inductors tend to bend to the inner side of the inductors in the vicinity of both ends of the inductors. The unintended bending causes the deterioration in the inductor characteristics.

In consideration with the circumstances, a main object of the disclosure is to provide an inductor array chip and a DC-to-DC converter module that can keep flatness of a multilayer body in which a plurality of inductors having inductance values at least one of which is different from other inductance values are provided, and can suppress the deterioration in the inductor characteristics.

An inductor array chip according to an aspect of the disclosure includes a multilayer body formed by laminating a plurality of ceramic sheets at least some of which have magnetism, and a plurality of inductors provided in the multilayer body and having a plurality of inductance values at least one of which is different from other inductance values, wherein each of the plurality of inductors is configured by a plurality of coiled conductors which are provided between the plurality of ceramic sheets and the number of which is common to the plurality of inductors, a first via hole conductor which spirally connects the plurality of coiled conductors, and a second via hole conductor which additionally connects at least two coiled conductors of the plurality of coiled conductors, which are close to an outermost layer of the multilayer body.

It is preferable that the at least two coiled conductors be coiled conductors respectively close to two outermost layers forming the multilayer body.

It is preferable that respective positions of the plurality of coiled conductors in a lamination direction be different between at least two of the plurality of inductors.

A DC-to-DC converter module according to another aspect of the disclosure includes a multilayer body formed by laminating a plurality of ceramic sheets at least some of which have magnetism, a plurality of inductors provided in the multilayer body and having a plurality of inductance values at least one of which is different from other inductance values, and a switching IC mounted on the multilayer body and connected to the plurality of inductors, wherein each of the plurality of inductors is configured by a plurality of coiled conductors which are provided between the plurality of ceramic sheets and the number of which is common to the plurality of inductors, a first via hole conductor which spirally connects the plurality of coiled conductors, and a second via hole conductor which additionally connects at least two coiled conductors of the plurality of coiled conductors, which are close to an outermost layer of the multilayer body.

The coiled conductors forming each inductor are provided between the laminated ceramic sheets and the number of coiled conductors is common to the inductors. With this configuration, the flatness of the multilayer body is kept.

Further, the at least two coiled conductors forming each inductor are additionally connected by the second via hole conductor. With this configuration, an inductor value can be arbitrarily adjusted.

Moreover, the coiled conductors which are connected by the second via hole conductor are provided at positions close to the outermost layer of the multilayer body. With this configuration, a phenomenon that magnetic lines generated on each inductor bend to the inner side of a wound body in the vicinity of the outermost layer can be suppressed, and the deterioration in the inductor characteristics can be suppressed eventually.

The above-mentioned object, another object, characteristics, and advantages of the disclosure will be further clarified from the following detail description of embodiments, which are made with reference to the drawings.

### BRIEF DESCRIPTION OF THE SEVERAL VIEWS OF THE DRAWINGS

FIG. 1 is an exploded view illustrating a part of an inductor array chip in an exploded state in an embodiment.

FIG. 2 is an exploded view illustrating another part of the inductor array chip in the exploded state in the embodiment.

FIG. 3A is a plan view illustrating an example of a ceramic sheet SH0 forming the inductor array chip and FIG. 3B is a plan view illustrating an example of a ceramic sheet SH1 forming the inductor array chip.

FIG. 4A is a plan view illustrating an example of a ceramic sheet SH2 forming the inductor array chip and FIG. 4B is a plan view illustrating an example of a ceramic sheet SH3, SH5 or SH9 forming the inductor array chip.

FIG. 5A is a plan view illustrating an example of a ceramic sheet SH7 forming the inductor array chip and FIG. 5B is a plan view illustrating an example of a ceramic sheet SH11 forming the inductor array chip.

FIG. 6A is a plan view illustrating an example of a ceramic sheet SH6, SH8 or SH10 forming the inductor array chip and FIG. 6B is a plan view illustrating an example of a ceramic sheet SH4 forming the inductor array chip.

FIG. 7A is a plan view illustrating an example of a ceramic sheet SH12 forming the inductor array chip and FIG. 7B is a plan view illustrating an example of a ceramic sheet SH13 forming the inductor array chip.

FIG. 8 is a perspective view illustrating outer appearance of the inductor array chip in the embodiment.

FIG. 9A is a cross-sectional view cut along a line A-A of the inductor array chip as illustrated in FIG. 8 and FIG. 9B is a cross-sectional view cut along a line B-B of the inductor array chip as illustrated in FIG. 8.

FIG. 10A is a graphic explanation view illustrating main parts of the laminated ceramic sheets SH10 and SH11 and FIG. 10B is a graphic explanation view illustrating main parts of the laminated ceramic sheets SH3 and SH4.

FIG. 11A is a circuit diagram illustrating a partial inductor formed by coil conductor patterns CP103 and CP113, a via hole conductor VH113b, and an additional via hole conductor VH113c and FIG. 11B is a circuit diagram illustrating a partial inductor formed by coil conductor patterns CP31 and CP41, a via hole conductor VH41b, and an additional via hole conductor VH41c.

FIG. 12 is a graphic explanation view illustrating an example of magnetic lines generated on an inductor IDT1.

FIG. 13A is a graphic explanation view illustrating a part of the configuration of an inductor provided on an inductor array chip in another embodiment and FIG. 13B is a graphic explanation view illustrating a part of the configuration of an inductor provided on an inductor array chip in still another embodiment.

FIG. 14A is a cross-sectional view illustrating a cross section of an inductor array chip in still another embodiment and FIG. 14B is a cross-sectional view illustrating another cross section of the inductor array chip in still another embodiment.

FIG. 15 is a graphic explanation view schematically illustrating a part of the configuration of the inductor in the embodiment.

FIG. 16 is a graphic explanation view illustrating a path of an electric current flowing through the inductor as illustrated in FIG. 15.

FIG. 17 is a graphic explanation view schematically illustrating a part of the configuration of an inductor in another embodiment.

FIG. 18 is a graphic explanation view illustrating a path of an electric current flowing through the inductor as illustrated in FIG. 17.

FIG. 19 is a perspective view illustrating a DC-to-DC converter module in another embodiment.

FIG. 20 is a circuit diagram illustrating an example of the configuration of the DC-to-DC converter module as illustrated in FIG. 19.

### DETAILED DESCRIPTION OF THE DISCLOSURE

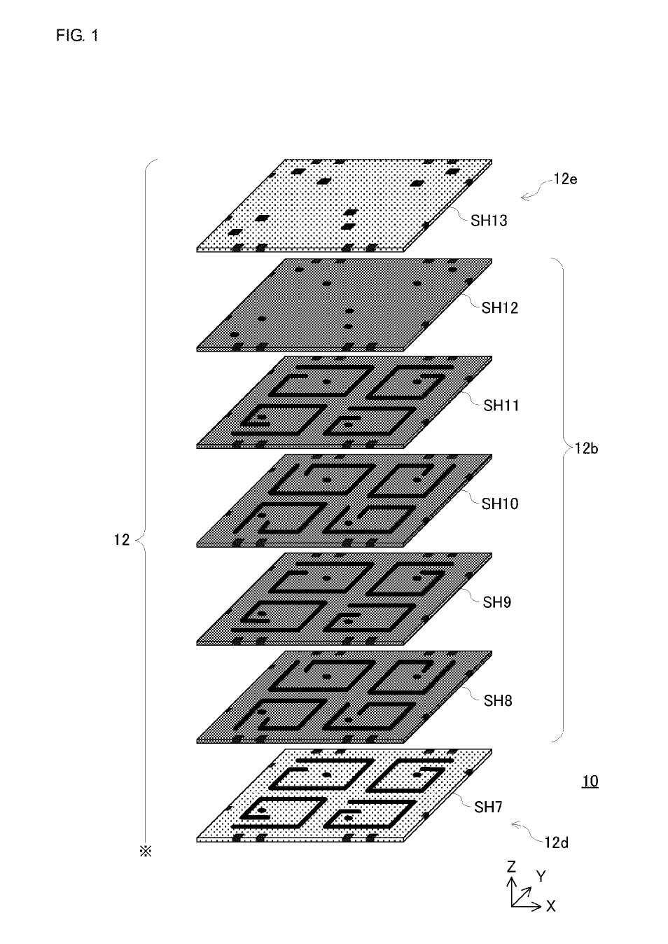

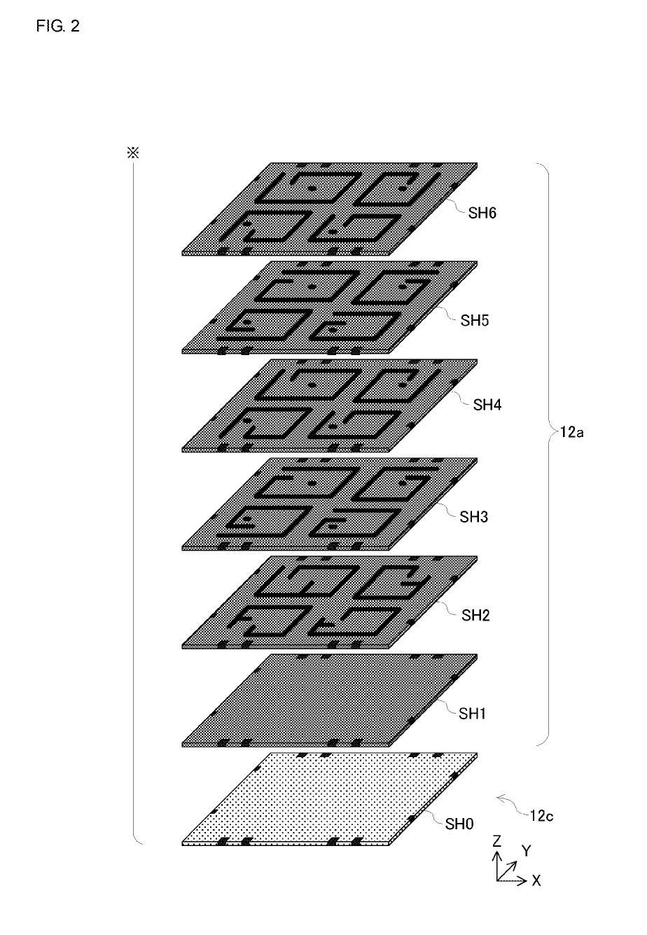

With reference to FIG. 1 and FIG. 2, an inductor array chip 10 in an embodiment is applied to a multi-channel DC-to-DC converter which outputs a plurality of DC voltages at least one voltage value of which is different from other voltage values or a plurality of DC currents at least one current value of which is different from other current values at the same time, and includes laminated ceramic sheets SH0 to SH13 having rectangular main surfaces. Sizes of the respective main surfaces of the ceramic sheets SH0 to SH13 are identical to one another and the ceramic sheets SH0 to SH13 are laminated in this order. The ceramic sheets SH0, SH7, and SH13 include non-magnetic substances whereas other ceramic sheets SH1 to SH6 and SH8 to SH12 include magnetic substances.

A multilayer body 12 has a rectangular parallelepiped shape, the ceramic sheets SH1 to SH6 form a magnetic layer 12a, the ceramic sheets SH8 to SH12 form a magnetic layer 12b, the ceramic sheet SH0 forms a non-magnetic layer 12c, the ceramic sheet SH7 forms a non-magnetic layer 12d, and the ceramic sheet SH13 forms a non-magnetic layer 12e.

That is to say, the multilayer body 12 configuring the inductor array chip 10 has a lamination configuration in which the magnetic layer 12a is held between the non-magnetic layers 12c and 12d and the magnetic layer 12b is held between the non-magnetic layers 12d and 12e. The long sides and the short sides of the rectangle forming the main surface (=the upper surface or the lower surface) of the multilayer body 12 extend along an X axis and a Y axis, and the thickness of the multilayer body 12 is increased along a Z axis.

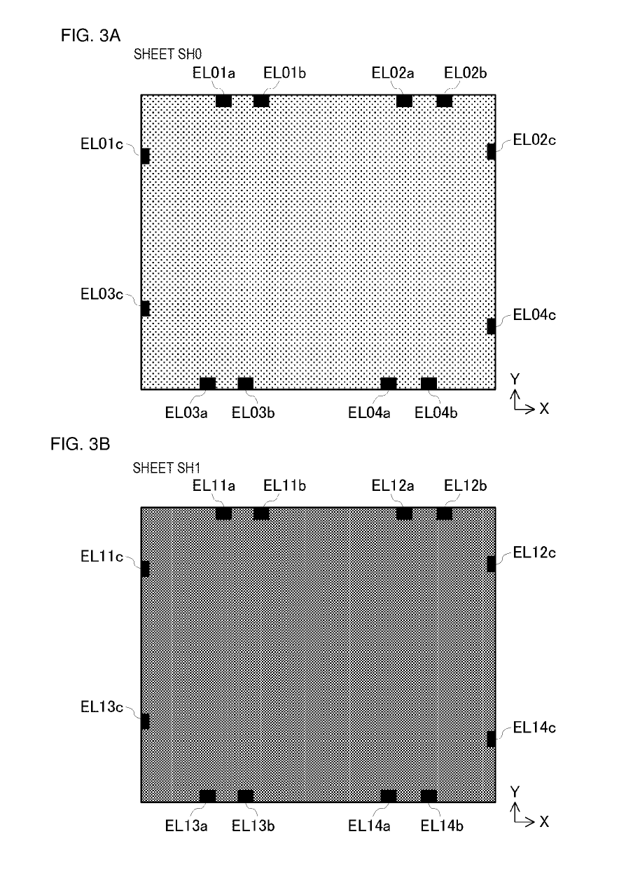

With reference to FIG. 3A, via hole conductors EL01a to EL01c, EL02a to EL02c, EL03a to EL03c, and EL04a to EL04c reaching the lower surface of the ceramic sheet SH0 are formed on end portions or edge portions of the upper surface thereof. The via hole conductors EL01a, EL01b, EL02a, and EL02b are aligned along the long side at the positive side in the Y-axis direction and the via hole conductors EL03a, EL03b, EL04a, and EL04b are aligned along the long side at the negative side in the Y-axis direction. The via hole conductors EL01c and EL03c are aligned along the short side at the negative side in the X-axis direction and the via hole conductors EL02c and EL04c are aligned along the short side at the positive side in the X-axis direction.

The via hole conductors EL01a to EL01c correspond to a channel CH1 and are gathered in the vicinity of a corner portion at the negative side in the X-axis direction and at the positive side in the Y-axis direction. The via hole conductors EL02a to EL02c correspond to a channel CH2 and are gathered in the vicinity of a corner portion at the positive side in the X-axis direction and at the positive side in the Y-axis direction. The via hole conductors EL03a to EL03c correspond to a channel CH3 and are gathered in the vicinity of a corner portion at the negative side in the X-axis direction and at the negative side in the Y-axis direction. The via hole conductors EL04a to EL04c correspond to a channel CH4 and are gathered in the vicinity of a corner portion at the positive side in the X-axis direction and at the negative side in the Y-axis direction.

With reference to FIG. 3B, via hole conductors EL11a to EL11c, EL12a to EL12c, EL13a to EL13c, and EL14a to EL14c reaching the lower surface of the ceramic sheet SH1 are formed on end portions or edge portions of the upper surface thereof. The via hole conductors EL11a to EL11c correspond to the channel CH1 and the via hole conductors EL12a to EL12c correspond to the channel CH2. The via hole conductors EL13a to EL13c correspond to the channel CH3 and the via hole conductors EL14a to EL14c correspond to the channel CH4.

When observed from the lamination direction in a state where the ceramic sheet SH1 is laminated on the ceramic sheet SH0, the via hole conductors EL11a to EL11c, EL12a to EL12c, EL13a to EL13c, and EL14a to EL14c overlap with the via hole conductors EL01a to EL01c, EL02a to EL02c, EL03a to EL03c, and EL04a to EL04c, respectively.

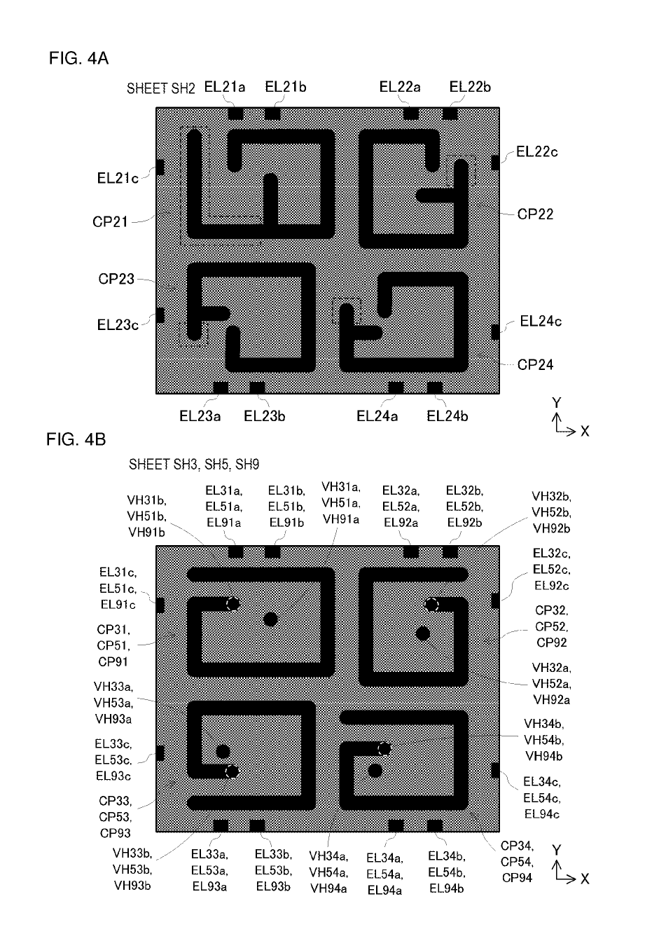

With reference to FIG. 4A, via hole conductors EL21a to EL21c, EL22a to EL22c, EL23a to EL23c, and EL24a to EL24c reaching the lower surface of the ceramic sheet SH2 are formed on end portions or edge portions of the upper surface thereof. The via hole conductors EL21a to EL21c correspond to the channel CH1 and the via hole conductors EL22a to EL22c correspond to the channel CH2. The via hole conductors EL23a to EL23c correspond to the channel CH3 and the via hole conductors EL24a to EL24c correspond to the channel CH4.

When observed from the lamination direction in a state where the ceramic sheet SH2 is laminated on the ceramic sheet SH1, the via hole conductors EL21a to EL21c, EL22a to EL22c, EL23a to EL23c, and EL24a to EL24c overlap with the via hole conductors EL11a to EL11c, EL12a to EL12c, EL13a to EL13c, and EL14a to EL14c, respectively.

Coil conductor patterns CP21 to CP24 corresponding to the channels CH1 to CH4, respectively, are also formed on the upper surface of the ceramic sheet SH2. The coil conductor pattern CP21 is provided in a region at the negative side in the X-axis direction and at the positive side in the Y-axis direction, that is, in an upper left region and the coil conductor pattern CP22 is provided in a region at the positive side in the X-axis direction and at the positive side in the Y-axis direction, that is, in an upper right region. Further, the coil conductor pattern CP23 is provided in a region at the negative side in the X-axis direction and at the negative side in the Y-axis direction, that is, in a lower left region and the coil conductor pattern CP24 is provided in a region at the positive side in the X-axis direction and at the negative side in the Y-axis direction, that is, in a lower right region.

When partial conductor patterns belonging to regions of the respective coil conductor patterns CP21 to CP24, which are surrounded by dashed lines, are defined as “extra conductor patterns”, the respective coil conductor patterns CP21 to CP24 form loops while excluding the extra conductor patterns.

The loop formed by the coil conductor pattern CP21 extends in the counterclockwise direction while a substantially center position in the upper left region is set to a starting end and a slightly upper left position relative to the starting end is set to a terminating end. The loop formed by the coil conductor pattern CP22 extends in the clockwise direction while a substantially center position in the upper right region is set to a starting end and a slightly upper right position relative to the starting end is set to a terminating end.

The loop formed by the coil conductor pattern CP23 extends in the clockwise direction while a substantially center position in the lower left region is set to a starting end and a slightly lower right position relative to the starting end is set to a terminating end. The loop formed by the coil conductor pattern CP24 extends in the counterclockwise direction while a substantially center position in the lower right region is set to a starting end and a slightly upper right position relative to the starting end is set to a terminating end.

With reference to FIG. 4B, via hole conductors EL31a to EL31c, EL32a to EL32c, EL33a to EL33c, and EL34a to EL34c reaching the lower surface of the ceramic sheet SH3 are formed on end portions or edge portions of the upper surface thereof. The via hole conductors EL31a to EL31c correspond to the channel CH1 and the via hole conductors EL32a to EL32c correspond to the channel CH2. The via hole conductors EL33a to EL33c correspond to the channel CH3 and the via hole conductors EL34a to EL34c correspond to the channel CH4.

When observed from the lamination direction in a state where the ceramic sheet SH3 is laminated on the ceramic sheet SH2, the via hole conductors EL31a to EL31c, EL32a to EL32c, EL33a to EL33c, and EL34a to EL34c overlap with the via hole conductors EL21a to EL21c, EL22a to EL22c, EL23a to EL23c, and EL24a to EL24c, respectively.

Via hole conductors VH31a to VH34a corresponding to the channels CH1 to CH4, respectively, are also formed on the upper surface of the ceramic sheet SH3. When observed from the lamination direction in a state where the ceramic sheet SH3 is laminated on the ceramic sheet SH2, the via hole conductor VH31a overlaps with the starting end of the loop formed by the coil conductor pattern CP21, the via hole conductor VH32a overlaps with the starting end of the loop formed by the coil conductor pattern CP22, the via hole conductor VH33a overlaps with the starting end of the loop formed by the coil conductor pattern CP23, and the via hole conductor VH34a overlaps with the starting end of the loop formed by the coil conductor pattern CP24.

Coil conductor patterns CP31 to CP34 corresponding to the channels CH1 to CH4, respectively, are also formed on the upper surface of the ceramic sheet SH3. The coil conductor pattern CP31 is provided in the upper left region in a loop form and the coil conductor pattern CP32 is provided in the upper right region in a loop form. The coil conductor pattern CP33 is provided in the lower left region in a loop form and the coil conductor pattern CP34 is provided in the lower right region in a loop form.

The coil conductor pattern CP31 extends in the counterclockwise direction around the via hole conductor VH31a while a slightly upper left position relative to the via hole conductor VH31a is set to a starting end and an upper left position of the upper left region is set to a terminating end. The coil conductor pattern CP32 extends in the clockwise direction around the via hole conductor VH32a while a slightly upper right position relative to the via hole conductor VH32a is set to a starting end and an upper right position of the upper right region is set to a terminating end.

The coil conductor pattern CP33 extends in the clockwise direction around the via hole conductor VH33a while a lower right position relative to the via hole conductor VH33a is set to a starting end and a lower left position of the lower left region is set to a terminating end. The coil conductor pattern CP34 extends in the counterclockwise direction around the via hole conductor VH34a while an upper right position relative to the via hole conductor VH34a is set to a starting end and an upper left position of the lower right region is set to a terminating end.

Via hole conductors VH31b to VH34b corresponding to the channels CH1 to CH4, respectively, are further formed on the upper surface of the ceramic sheet SH3. The via hole conductor VH31b is provided at the starting end of the coil conductor pattern CP31 and the via hole conductor VH32b is provided at the starting end of the coil conductor pattern CP32. The via hole conductor VH33b is provided at the starting end of the coil conductor pattern CP33 and the via hole conductor VH34b is provided at the starting end of the coil conductor pattern CP34.

The structures of via hole conductors and coil conductor patterns provided on the ceramic sheet SH5 and the SH9 are the same as those of the via hole conductors and the coil conductor patterns provided on the ceramic sheet SH3. Therefore, an upper-order one digit of two-digit numbers forming reference numerals, which is “3”, is replaced by “5” and “9” and overlapped description is omitted.

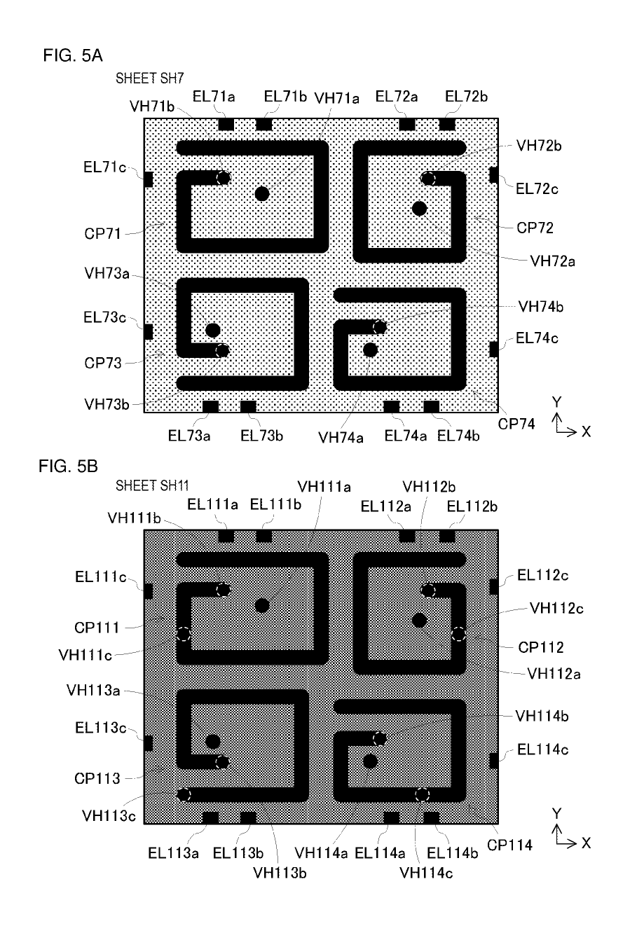

The ceramic sheet SH7 as illustrated in FIG. 5A includes the non-magnetic substance as described above. It should be noted that the structures of via hole conductors and coil conductor patterns provided on the ceramic sheet SH7 are also the same as those of the via hole conductors and the coil conductor patterns provided on the ceramic sheet SH3. Therefore, the upper-order one digit of the two-digit numbers forming the reference numerals, which is “3”, is replaced by “7” and overlapped description is omitted.

With reference to FIG. 5B, the structures of via hole conductors and coil conductor patterns provided on the ceramic sheet SH11 are substantially the same as those of the via hole conductors and the coil conductor patterns provided on the ceramic sheet SH3. Therefore, the upper-order one digit of the two-digit numbers forming the reference numerals, which is “3”, is replaced by “11” and overlapped description relating to the same configuration is omitted.

The ceramic sheet SH11 is different from the ceramic sheet SH3 in a point that additional via hole conductors VH111c to VH114c reaching the lower surface of the ceramic sheet SH111 from the upper surface thereof are added. The additional via hole conductor VH111c is provided at a position different from a starting end position and a terminating end position of a coil conductor pattern CP111 and overlapping with the coil conductor pattern CP111. The additional via hole conductor VH112c is provided at a position different from a starting end position and a terminating end position of a coil conductor pattern CP112 and overlapping with the coil conductor pattern CP112. The additional via hole conductor VH113c is provided at a terminating end position of a coil conductor pattern CP113. The additional via hole conductor VH114c is provided at a position different from a starting end position and a terminating end position of a coil conductor pattern CP114 and overlapping with the coil conductor pattern CP114.

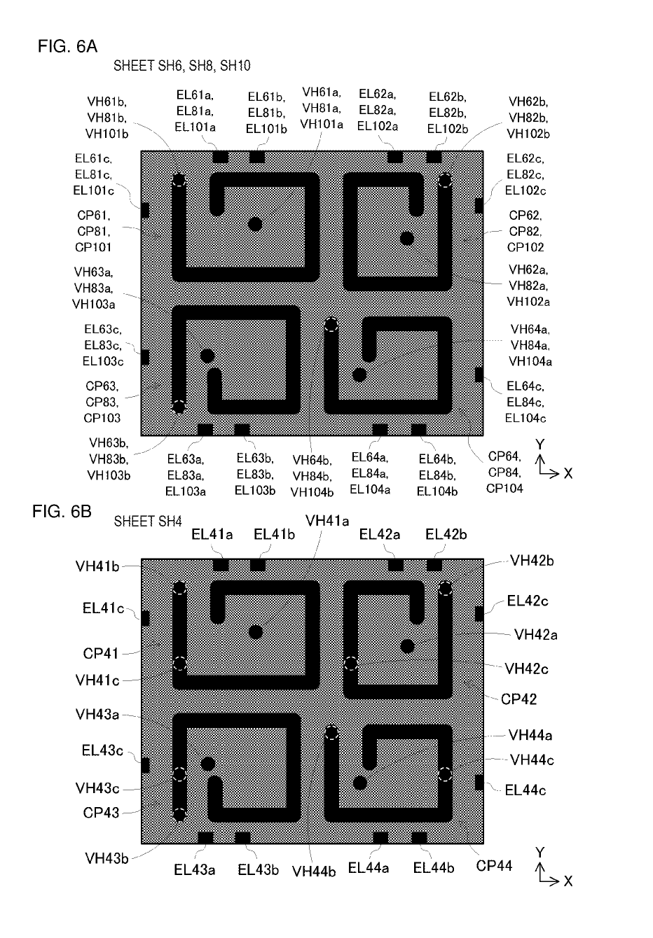

With reference to FIG. 6A, via hole conductors EL61a to EL61c, EL62a to EL62c, EL63a to EL63c, and EL64a to EL64c reaching the lower surface of the ceramic sheet SH6 are formed on end portions or edge portions of the upper surface thereof. The via hole conductors EL61a to EL61c correspond to the channel CH1 and the via hole conductors EL62a to EL62c correspond to the channel CH2. The via hole conductors EL63a to EL63c correspond to the channel CH3 and the via hole conductors EL64a to EL64c correspond to the channel CH4.

When observed from the lamination direction in a state where the ceramic sheet SH6 is laminated on the ceramic sheet SH5, the via hole conductors EL61a to EL61c, EL62a to EL62c, EL63a to EL63c, and EL64a to EL64c overlap with the via hole conductors EL51a to EL51c, EL52a to EL52c, EL53a to EL53c, and EL54a to EL54c, respectively.

Via hole conductors VH61a to VH64a corresponding to the channels CH1 to CH4, respectively, are also formed on the upper surface of the ceramic sheet SH6. When observed from the lamination direction in a state where the ceramic sheet SH6 is laminated on the ceramic sheet SH5, the via hole conductors VH61a to VH64a overlap with the via hole conductors VH51a to VH54a, respectively.

Coil conductor patterns CP61 to CP64 corresponding to the channels CH1 to CH4, respectively, are also formed on the upper surface of the ceramic sheet SH6. The coil conductor pattern CP61 is provided in the upper left region in a loop form and the coil conductor pattern CP62 is provided in the upper right region in a loop form. The coil conductor pattern CP63 is provided in the lower left region in a loop form and the coil conductor pattern CP64 is provided in the lower right region in a loop form.

The coil conductor pattern CP61 extends in the counterclockwise direction around the via hole conductor VH61a while an upper left position of the upper left region is set to a starting end and an upper left position relative to the via hole conductor VH61a is set to a terminating end. The coil conductor pattern CP62 extends in the clockwise direction around the via hole conductor VH62a while an upper right position of the upper right region is set to a starting end and an upper right position relative to the via hole conductor VH62a is set to a terminating end.

The coil conductor pattern CP63 extends in the clockwise direction around the via hole conductor VH63a while a lower left position of the lower left region is set to a starting end and a lower right position relative to the via hole conductor VH63a is set to a terminating end. The coil conductor pattern CP64 extends in the counterclockwise direction around the via hole conductor VH64a while an upper left position of the lower right region is set to a starting end and an upper right position relative to the via hole conductor VH64a is set to a terminating end.

Via hole conductors VH6lb to VH64b corresponding to the channels CH1 to CH4, respectively, are further formed on the upper surface of the ceramic sheet SH6. The via hole conductor VH6lb is provided at the starting end of the coil conductor pattern CP61 and the via hole conductor VH62b is provided at the starting end of the coil conductor pattern CP62. The via hole conductor VH63b is provided at the starting end of the coil conductor pattern CP63 and the via hole conductor VH64b is provided at the starting end of the coil conductor pattern CP64.

The structures of via hole conductors and coil conductor patterns provided on the ceramic sheet SH8 and SH10 are the same as those of the via hole conductors and the coil conductor patterns provided on the ceramic sheet SH6. Therefore, an upper-order one digit of two-digit numbers forming reference numerals, which is “6”, is replaced by “8” and “10” and overlapped description is omitted.

With reference to FIG. 6B, the structures of via hole conductors and coil conductor patterns provided on the ceramic sheet SH4 are substantially the same as those of the via hole conductors and the coil conductor patterns provided on the ceramic sheet SH6. Therefore, the upper-order one digit of the two-digit numbers forming the reference numerals, which is “6”, is replaced by “4” and overlapped description relating to the same configuration is omitted.

The ceramic sheet SH4 is different from the ceramic sheet SH6 in a point that additional via hole conductors VH41c to VH44c reaching the lower surface of the ceramic sheet SH4 from the upper surface thereof are added. The additional via hole conductor VH41c is provided at a position different from a starting end position and a terminating end position of a coil conductor pattern CP41 and overlapping with the coil conductor pattern CP41. The additional via hole conductor VH42c is provided at a position different from a starting end position and a terminating end position of a coil conductor pattern CP42 and overlapping with the coil conductor pattern CP42.

The additional via hole conductor VH43c is provided at a position different from a starting end position and a terminating end position of a coil conductor pattern CP43 and overlapping with the coil conductor pattern CP43. The additional via hole conductor VH44c is provided at a position different from a starting end position and a terminating end position of a coil conductor pattern CP44 and overlapping with the coil conductor pattern CP44.

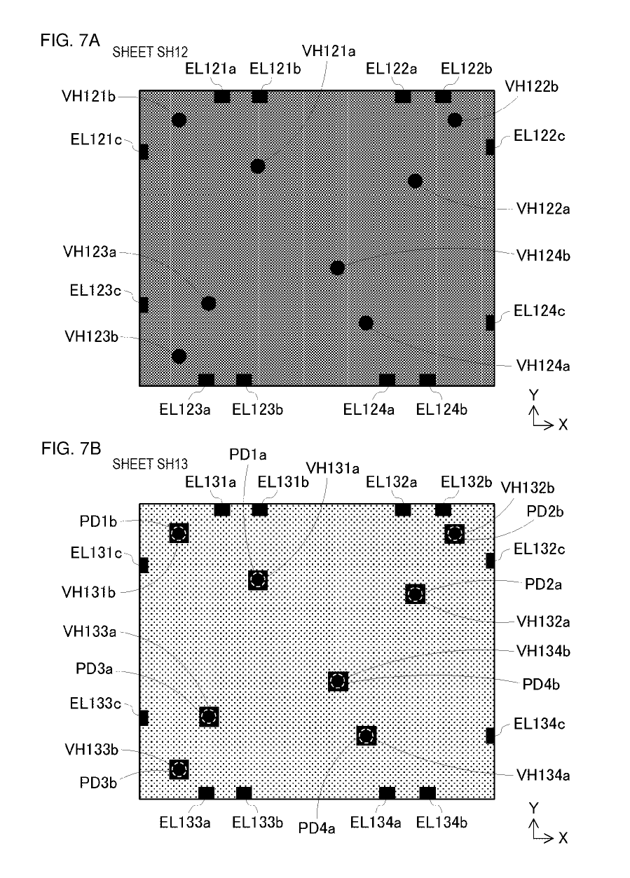

With reference to FIG. 7A, via hole conductors EL121a to EL121c, EL122a to EL122c, EL123a to EL123c, and EL124a to EL124c reaching the lower surface of the ceramic sheet SH12 are formed on end portions or edge portions of the upper surface thereof. The via hole conductors EL121a to EL121c correspond to the channel CH1 and the via hole conductors EL122a to EL122c correspond to the channel CH2. The via hole conductors EL123a to EL123c correspond to the channel CH3 and the via hole conductors EL124a to EL124c correspond to the channel CH4.

When observed from the lamination direction in a state where the ceramic sheet SH12 is laminated on the ceramic sheet SH11, the via hole conductors EL121a to EL121c, EL122a to EL122c, EL123a to EL123c, and EL124a to EL124c overlap with the via hole conductors EL111a to EL111c, EL112a to EL112c, EL113a to EL113c, and EL114a to EL114c, respectively.

Via hole conductors VH121a to VH124a and via hole conductors VH121b to VH124b are also formed on the upper surface of the ceramic sheet SH12. The via hole conductors VH121a and VH121b correspond to the channel CH1, the via hole conductor VH122a and VH122b correspond to the channel CH2, the via hole conductor VH123a and VH123b correspond to the channel CH3, and via hole conductor VH124a and VH124b correspond to the channel CH4.

When observed from the lamination direction in a state where the ceramic sheet SH12 is laminated on the ceramic sheet SH11, the via hole conductors VH121a to VH124a overlap with the via hole conductors VH111a to VH114a, respectively. The via hole conductor VH121b overlaps with the terminating end of the coil conductor pattern CP111, the via hole conductor VH122b overlaps with the terminating end of the coil conductor pattern CP112, the via hole conductor VH123b overlaps with the terminating end of the coil conductor pattern CP113, and the via hole conductor VH124b overlaps with the terminating end of the coil conductor pattern CP114.

With reference to FIG. 7B, via hole conductors EL131a to EL131c, EL132a to EL132c, EL133a to EL133c, and EL134a to EL134c reaching the lower surface of the ceramic sheet SH13 are formed on end portions or edge portions of the upper surface thereof. The via hole conductors EL131a to EL131c correspond to the channel CH1 and the via hole conductors EL132a to EL132c correspond to the channel CH2. The via hole conductors EL133a to EL133c correspond to the channel CH3 and the via hole conductors EL134a to EL134c correspond to the channel CH4.

When observed from the lamination direction in a state where the ceramic sheet SH13 is laminated on the ceramic sheet SH12, the via hole conductors EL131a to EL131c, EL132a to EL132c, EL133a to EL133c, and EL134a to EL134c overlap with the via hole conductors EL121a to EL121c, EL122a to EL122c, EL123a to EL123c, and EL124a to EL124c, respectively.

Via hole conductors VH131a to VH134a and via hole conductors VH131b to VH134b are also formed on the upper surface of the ceramic sheet SH13. The via hole conductors VH131a and VH131b correspond to the channel CH1, the via hole conductors VH132a and VH132b correspond to the channel CH2, the via hole conductors VH133a and VH133b correspond to the channel CH3, and the via hole conductors VH134a and VH134b correspond to the channel CH4.

When observed from the lamination direction in a state where the ceramic sheet SH13 is laminated on the ceramic sheet SH12, the via hole conductors VH131a to VH134a overlap with the via hole conductors VH121a to VH124a, respectively, and the via hole conductors VH131b to VH134b overlap with the via hole conductors VH121b to VH124b, respectively.

Pad electrodes PD1a to PD4a and PD1b to PD4b are further formed on the upper surface of the ceramic sheet SH13. The pad electrodes PD1a to PD4a are provided at positions covering the via hole conductors VH131a to VH134a and the pad electrodes PD1b to PD4b are provided at positions covering the via hole conductors VH131b to VH134b.

The ceramic sheets SH0 to SH13 are configured as described above. With this configuration, the coil conductor patterns CP21 to CP111 are spirally connected by the via hole conductor VH31a to VH131a and VH31b to VH131b and the coil conductor patterns CP22 to CP112 are spirally connected by the via hole conductors VH32a to VH132a and VH32b to VH132b. Further, the coil conductor patterns CP23 to CP113 are spirally connected by the via hole conductors VH33a to VH133a and VH33b to VH133b and the coil conductor patterns CP24 to CP114 are spirally connected by the via hole conductors VH34a to VH134a and VH34b to VH134b.

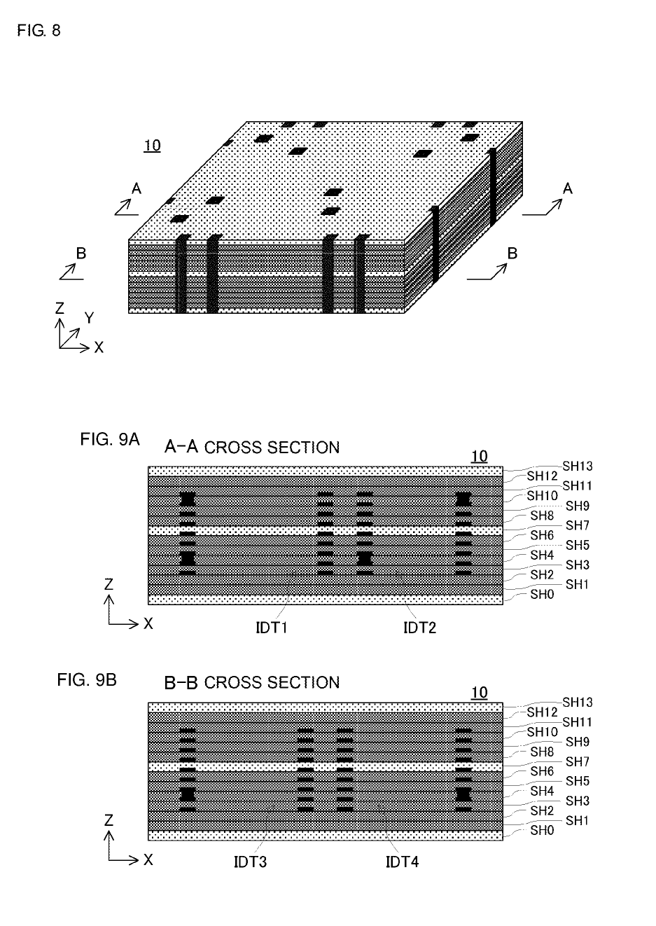

When the ceramic sheets SH0 to SH13 are laminated, the inductor array chip 10 as illustrated in FIG. 8 is produced. An A-A cross section and a B-B cross section of the inductor array chip 10 have the configurations as illustrated in FIG. 9A and FIG. 9B, respectively. As is seen from FIG. 9A and FIG. 9B, four inductors IDT1 to IDT4 wound about the Z axis as winding axes are formed in the inductor array chip 10.

It should be noted that passive elements such as a capacitor and a resistive element and active elements such as an IC and a field effect transistor (FET) (not illustrated) are mounted on the top surface of the ceramic sheet SH13. These elements are connected to the pad electrodes PD1a to PD4a, and PD1b to PD4b and the via hole conductors EL131a to EL131c, EL132a to EL132c, EL133a to EL133c, and EL134a to EL134c.

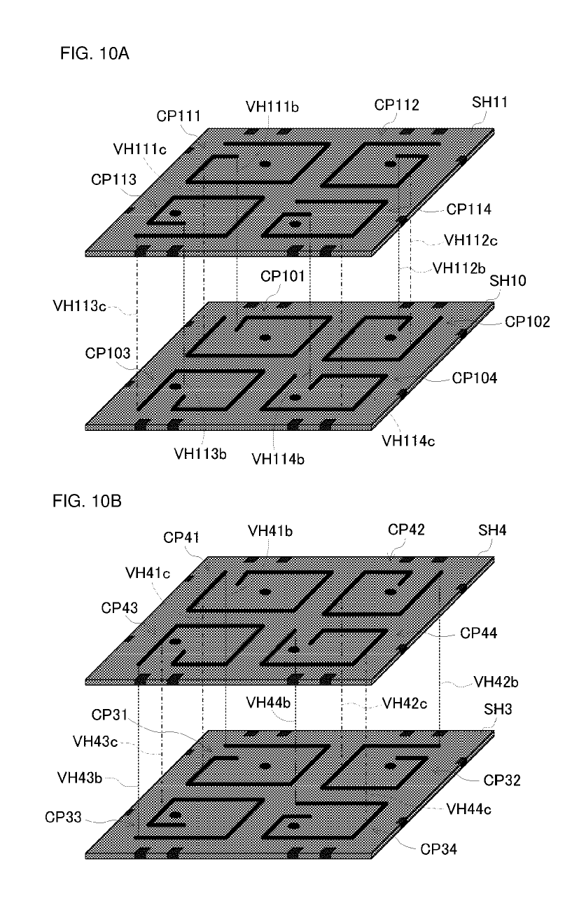

In this embodiment, the coil conductor patterns CP101 and CP111 are additionally connected by the additional via hole conductor VH111c, the coil conductor patterns CP102 and CP112 are additionally connected by the additional via hole conductor VH112c, the coil conductor patterns CP103 and CP113 are additionally connected by the additional via hole conductor VH113c, and the coil conductor patterns CP104 and CP114 are additionally connected by the additional via hole conductor VH114c (see FIG. 10A).

Further, the coil conductor patterns CP31 and CP41 are additionally connected by the additional via hole conductor VH41c, the coil conductor patterns CP32 and CP42 are additionally connected by the additional via hole conductor VH42c, the coil conductor patterns CP33 and CP43 are additionally connected by the additional via hole conductor VH43c, and the coil conductor patterns CP34 and CP44 are additionally connected by the additional via hole conductor VH44c (see FIG. 10B).

An inductance value of the inductor IDT1 is finely adjusted by the additional via hole conductors VH4lc and VH111c, an inductance value of the inductor IDT2 is finely adjusted by the additional via hole conductors VH42c and VH112c, an inductance value of the inductor IDT3 is finely adjusted by the additional via hole conductors VH43c and VH113c, and an inductance value of the inductor IDT4 is finely adjusted by the additional via hole conductors VH44c and VH114c.

With this, the inductance values can be set to desired values without changing the wiring widths or the thicknesses of the coil conductor patterns CP21 to CP111, CP22 to CP112, CP23 to CP113, and CP24 to CP114 or the number of coil conductor patterns (that is, without deteriorating the flatness of the multilayer body 12).

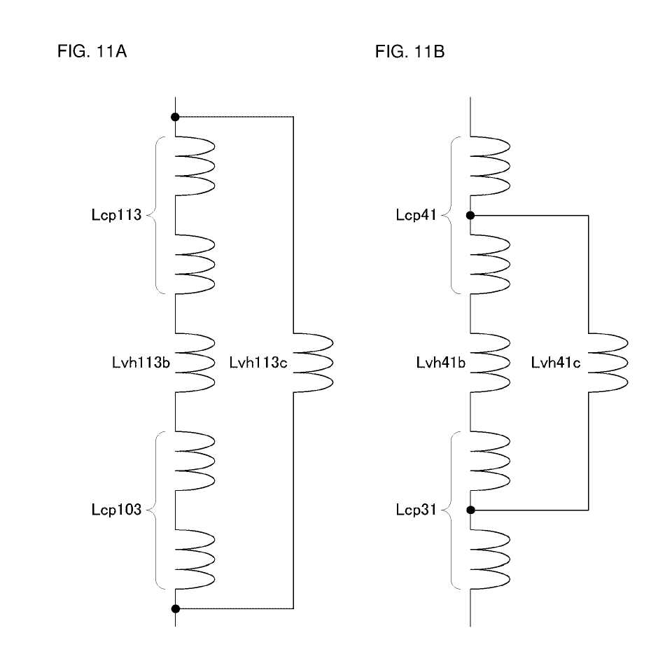

For example, when an inductor component of the coil conductor pattern CP103 is defined as “Lcp103”, an inductor component of the coil conductor pattern CP113 is defined as “Lcp113”, an inductor component of the via hole conductor VH113b is defined as “Lvh113b”, and an inductor component of the additional via hole conductor VH113c is defined as “Lvh113c”, these inductor components are connected as illustrated in FIG. 11A. That is to say, the inductor components Lcp103, Lvh113b, and Lcp113 are connected in series and the inductor component Lvh113c is connected to the three inductor components in parallel or in a short-circuit state.

Further, when an inductor component of the coil conductor pattern CP31 is defined as “Lcp31”, an inductor component of the coil conductor pattern CP41 is defined as “Lcp41”, an inductor component of the via hole conductor VH4lb is defined as “Lvh41b”, and an inductor component of the additional via hole conductor VH41c is defined as “Lvh41c”, these inductor components are connected as illustrated in FIG. 11B. That is to say, the inductor components Lcp31, Lvh41b, and Lcp41 are connected in series and the inductor component Lvh41c is connected to a part of these inductor components in parallel or in a short-circuit state.

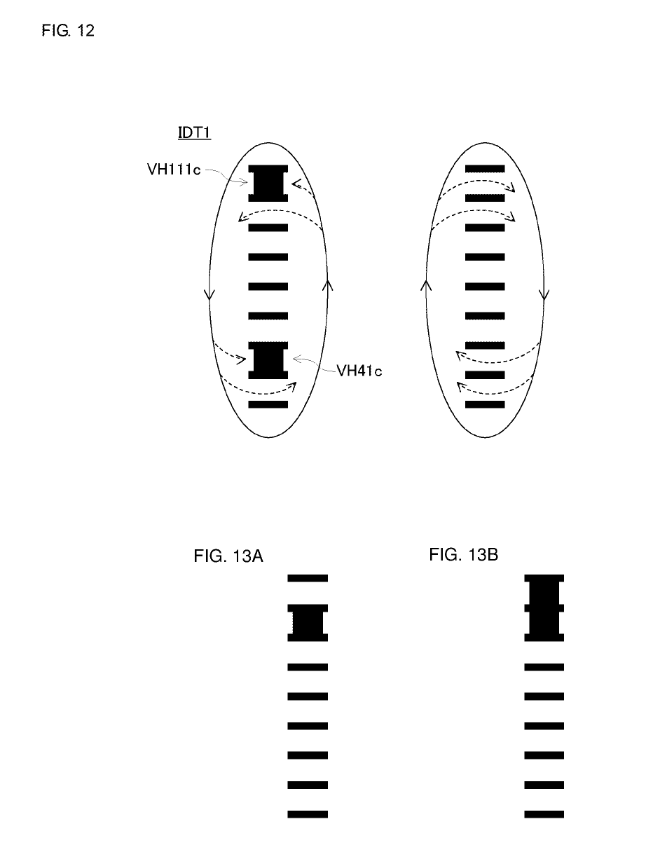

For example, magnetic lines are generated on the inductor IDT1 as illustrated in FIG. 12. That is to say, the magnetic lines bend to the inner side of the inductor IDT1 in the vicinity of both ends of the inductor IDT1. In order to cope with this, the additional via hole conductors VH41c and VH111c are provided in the vicinity of both ends of the inductor IDT1 (that is, at positions close to the outermost layers of the multilayer body 12). Therefore, bending of the magnetic lines to the inner side of the inductor IDT1 is suppressed, and the deterioration in the characteristics of the inductor IDT1 is suppressed eventually.

It should be noted that the ceramic sheets SH0, SH7, and SH13 are made of non-magnetic ferrite (relative magnetic permeability: 1) as a material and thermal expansion coefficients thereof indicate values in a range of “8.5” to “9.0”. Further, the ceramic sheets SH1 to SH6 and SH8 to SH12 are made of magnetic ferrite (relative magnetic permeability: 100 to 120) as a material and thermal expansion coefficients thereof indicate values in a range of “9.0” to “10.0”. In addition, the pad electrodes PD1a to PD4a and PD1b to PD4b, the coil conductor patterns CP21 to CP111, CP22 to CP112, CP23 to CP113, and CP24 to CP114, the via hole conductors VH31a to VH131a and VH31b to VH131b, the via hole conductors VH32a to VH132a and VH32b to VH132b, the via hole conductors VH33a to VH133a and VH33b to VH133b, the via hole conductors VH34a to VH134a and VH34b to VH134b, and the additional via hole conductors VH41c to VH44c and VH111c to VH114c are made of silver as a material, and thermal expansion coefficients thereof indicate “20”.

As is seen from the above description, the multilayer body 12 is produced by laminating the plurality of ceramic sheets SH0 to SH13 at least some of which have magnetism. The inductors IDT1 to IDT4 have a plurality of inductance values at least one of which is different from other inductance values, and are provided in the multilayer body 12.

The numbers of coil conductor patterns CP21 to CP111 forming the inductor IDT1, coil conductor patterns CP22 to CP112 forming the inductor IDT2, coil conductor patterns CP23 to CP113 forming the inductor IDT3, and coil conductor patterns CP24 to CP114 forming the inductor IDT4 are common to the channels and they are provided between the ceramic sheet SH2 to SH12.

The coil conductor patterns CP21 to CP111 are spirally connected by the via hole conductors VH31a to VH131a and VH31b to VH131b and the coil conductor patterns CP22 to CP112 are spirally connected by the via hole conductors VH32a to VH132a and VH32b to VH132b. The coil conductor patterns CP23 to CP113 are spirally connected by the via hole conductors VH33a to VH133a and VH33b to VH133b and the coil conductor patterns CP24 to CP114 are spirally connected by the via hole conductors VH34a to VH134a and VH34b to VH134b.

Further, the coil conductor patterns CP31 and CP41 are additionally connected by the additional via hole conductor VH41c and the coil conductor patterns CP32 and CP42 are additionally connected by the additional via hole conductor VH42c. The coil conductor patterns CP33 and CP43 are additionally connected by the additional via hole conductor VH43c and the coil conductor patterns CP34 and CP44 are additionally connected by the additional via hole conductor VH44c.

In the same manner, the coil conductor patterns CP101 and CP111 are additionally connected by the additional via hole conductor VH111c and the coil conductor patterns CP102 and CP112 are additionally connected by the additional via hole conductor VH112c. The coil conductor patterns CP103 and CP113 are additionally connected by the additional via hole conductor VH113c and the coil conductor patterns CP104 and CP114 are additionally connected by the additional via hole conductor VH114c.

Thus, the coil conductor patterns forming the respective inductors are provided between the laminated ceramic sheets and the numbers of coil conductor patterns aligned in the lamination direction are common to the inductors. With this, the flatness of the multilayer body is kept. At least two coiled conductors forming each of the inductors are additionally connected by the additional via hole conductor. This enables the inductor value to be adjusted arbitrarily. In addition, the coil conductor patterns that are connected by the additional via hole conductors are provided at positions close to the outermost layer of the multilayer body. With this configuration, a phenomenon that magnetic lines generated on each inductor bend to the inner side of a wound body in the vicinity of the outermost layer can be suppressed, and the deterioration in the inductor characteristics can be suppressed eventually.

In the embodiment, the additional via hole conductors VH41c to VH44c are provided at positions close to one outermost layer forming the multilayer body 12 and the additional via hole conductors VH111c to VH114c are provided at positions close to the other outermost layer forming the multilayer body 12. However, the additional via hole conductors may be formed at only positions close to any one of the outermost layers (see FIG. 13A) or the additional via hole conductors may be formed over three layers (see FIG. 13B).

Some coil conductor patterns may be removed and a removable position thereof may be made different among the channels as long as the number of coil conductor patterns is common to the channels (see FIG. 14A to FIG. 14B).

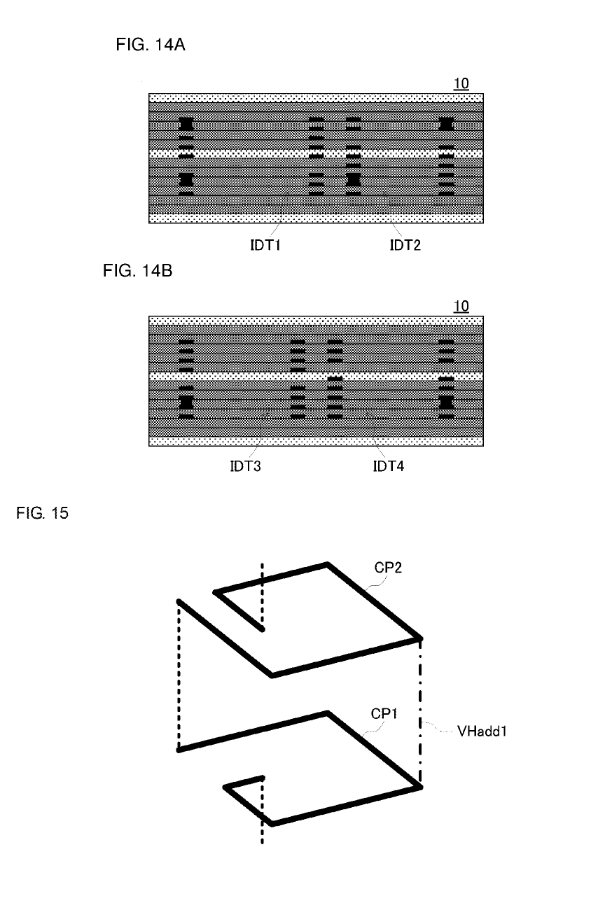

Moreover, in the embodiment, as schematically illustrated in FIG. 15, two coil conductor patterns CP1 and CP2 adjacent in the lamination direction are additionally connected by a single additional via hole conductor VHadd1. Alternatively, the two coil conductor patterns CP1 and CP2 adjacent in the lamination direction may be connected by a plurality of additional via hole conductors VHadd1 and VHadd2 as illustrated in FIG. 17.

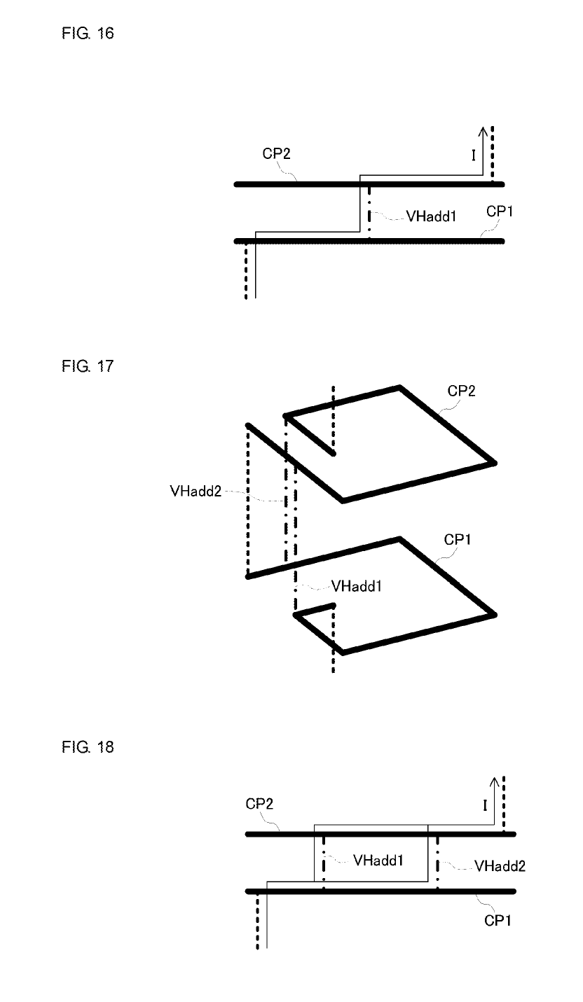

In the case of the configuration as illustrated in FIG. 15, an electric current I flowing to the coil conductor pattern CP2 from the coil conductor pattern CP1 is shortcut by the additional via hole conductor VHadd1 as illustrated in FIG. 16. An electrode portion through which no current flows is generated on each of the coil conductor patterns CP1 and CP2. By contrast, in the case of the configuration as illustrated in FIG. 17, a current flowing to the coil conductor pattern CP2 from the coil conductor pattern CP1 is made to branch by the additional via hole conductors VHadd1 and VHadd2 as illustrated in FIG. 18. Although the electrode portions through which no current flows are also generated in the configuration as illustrated in FIG. 17, the lengths of the electrode portions are smaller than those in the configuration as illustrated in FIG. 15.

As a result, an inductance value when the configuration as illustrated in FIG. 17 is employed is identical to an inductance value when the configuration as illustrated in FIG. 15 is employed. However, a resistance value when the configuration as illustrated in FIG. 17 is employed can be reduced from that when the configuration as illustrated in FIG. 15 is employed. That is to say, conductor loss can be reduced by connecting the coil conductor patterns CP1 and CP2 by the plurality of additional via hole conductors VHadd1 and VHadd2.

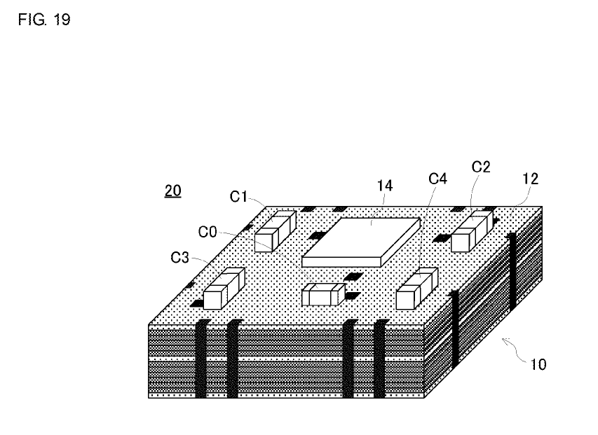

FIG. 19 illustrates a DC-to-DC converter module 20 using the inductor array chip 10 in the embodiment. With reference to FIG. 19, capacitors C0 to C4 and a switching IC 14 are mounted on the top surface of the multilayer body 12 configuring the inductor array chip 10. A conductive bonding member such as solder is used for mounting.

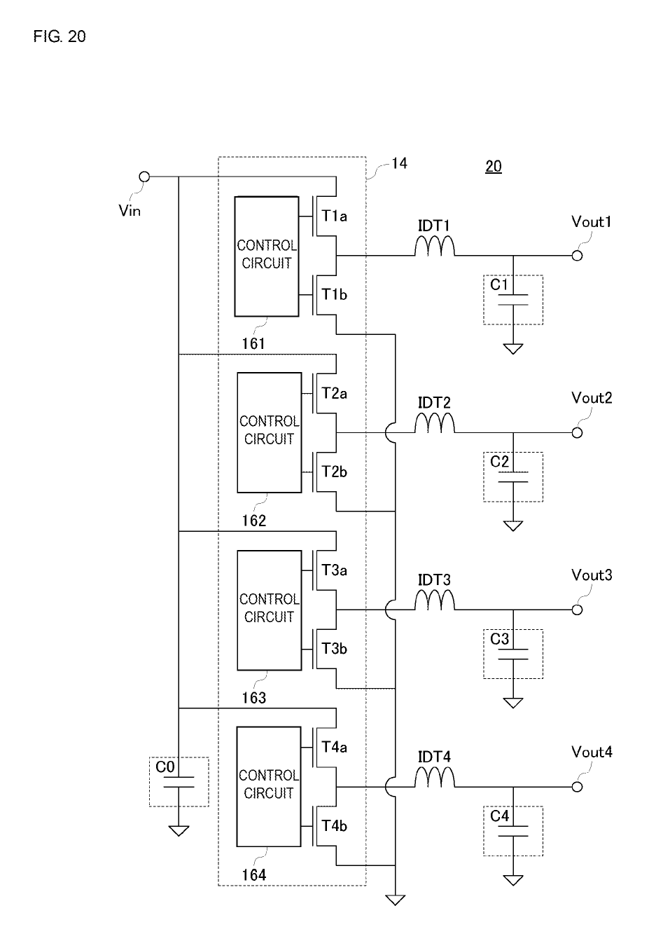

The inductors IDT1 to IDT4 provided in the inductor array chip 10 are connected to the capacitors C0 to C4 and the switching IC 14 in a manner as illustrated in FIG. 20. It should be noted that in FIG. 20, wirings and the inductors IDT1 to IDT4 provided on outer side portions of rectangles as drawn by dashed lines are formed in the inductor array chip 10.

With reference to FIG. 20, the switching IC 14 includes control circuits 161 to 164 corresponding to the channels CH1 to CH4, respectively. Further, MOS transistors T1a and T1b are assigned to the control circuit 161, MOS transistors T2a and T2b are assigned to the control circuit 162, MOS transistors T3a and T3b are assigned to the control circuit 163, and MOS transistors T4a and T4b are assigned to the control circuit 164.

One ends of the transistors T1a to T4a are commonly connected to an input terminal Vin, and the other ends of the transistors T1a to T4a are connected to one ends of the transistors T1b to T4b, respectively. The other ends of the transistors T1b to T4b are commonly connected to a reference potential surface. The control circuit 161 turns ON/OFF the transistors T1a and T1b alternately or turns OFF both the transistors T1a and Tlb, the control circuit 162 turns ON/OFF the transistors T2a and T2b alternately or turns OFF both the transistors T2a and T2b, the control circuit 163 turns ON/OFF the transistors T3a and T3b alternately or turns OFF both the transistors T3a and T3b, and the control circuit 164 turns ON/OFF the transistors T4a and T4b alternately or turns OFF both the transistors T4a and T4b.

The inductor IDT1 is provided between a connection point of the transistor T1a and the transistor T1b and an output terminal Vout1, the inductor IDT2 is provided between a connection point of the transistor T2a and the transistor T2b and an output terminal Vout2, the inductor IDT3 is provided between a connection point of the transistor T3a and the transistor T3b and an output terminal Vout3, and the inductor IDT4 is provided between a connection point of the transistor T4a and the transistor T4b and an output terminal Vout4.

The capacitor C0 is provided between the input terminal Vin and the reference potential surface, the capacitor C1 is provided between the output terminal Vout1 and the reference potential surface, the capacitor C2 is provided between the output terminal Vout2 and the reference potential surface, the capacitor C3 is provided between the output terminal Vout3 and the reference potential surface, and the capacitor C4 is provided between the output terminal Vout4 and the reference potential surface.

In this embodiment, the DC-to-DC converter module 20 functions as a switching power supply for the plurality of channels. In this case, the flatness of the top surface of the multilayer body 12 is preferable and the DC-to-DC converter module 20 functions as the switching power supply with less deterioration of the inductors IDT1 to IDT4, that is, with preferable manufacturing performance and electric characteristics even when the inductance values of the inductors IDT1 to IDT4 are adjusted for the respective channels.

In the embodiment, all the channels CH1 to CH4 are of a step-down type. However, switching power supply circuits of various systems using inductors of a step-up type, a step-up/step-down type, an inversion-type, or the like may be formed for all or some of the plurality of channels.

In the embodiment, the channels CH1 to CH4 are integrated into the switching IC 14. However, four switching ICs corresponding to the respective channels CH1 to CH4 may be mounted on the multilayer body 12 or a switching IC corresponding to some channels of the channels CH1 to CH4 and another switching IC corresponding to the other channels may be combined to be mounted on the multilayer body 12.
10 INDUCTOR ARRAY CHIP
12 MULTILAYER BODY
14 SWITCHING IC
161 TO 164 CONTROL CIRCUIT
20 DC-TO-DC CONVERTER MODULE
SH0 TO SH13 CERAMIC SHEET
IDT1 TO IDT4 INDUCTOR
CP21 TO 111, CP22 TO 112, CP23 TO 113, CP24 TO 114 COIL CONDUCTOR PATTERN (COILED CONDUCTOR)
VH31a TO VH131a, VH31b TO VH131b, VH32a TO VH132a, VH32b TO VH132b, VH33a TO VH133a, VH33b TO VH133b, VH34a TO VH134a, AND VH34b TO VH134b VIA HOLE CONDUCTOR (FIRST VIA HOLE CONDUCTOR)
VH41c TO VH44c AND VH111c TO VH114c ADDITIONAL VIA HOLE CONDUCTOR (SECOND VIA HOLE CONDUCTOR)

1. An inductor array chip comprising:
a multilayer body formed by laminating a plurality of ceramic sheets, wherein at least some of the plurality of ceramic sheets have magnetism; and
a plurality of inductors provided in the multilayer body,
wherein each of the plurality of inductors includes:
a plurality of coiled conductors provided between the plurality of ceramic sheets, wherein each of the plurality of inductors has a same number of the plurality of coiled conductors;
a first via hole conductor spirally connecting the plurality of coiled conductors; and
a second via hole conductor additionally connecting at least two coiled conductors of the plurality of coiled conductors located close to an outermost layer of the multilayer body, and connecting a part of the at least two coiled conductors in parallel or in a short-circuit manner, and
at least one of the plurality of inductors has an inductance value different from inductance values of other inductors.

2. The inductor array chip according to claim 1,
wherein the second via hole conductor is provided at a position different from starting end positions and terminating end positions of the coiled conductors.

3. The inductor array chip according to claim 1,
wherein the first via hole conductor is provided at a position different from the second via hole conductor.

4. The inductor array chip according to claim 1,
wherein the second via hole conductors are provided at each of a position close to one outermost layer of the multilayer body and a position close to another outermost layer of the multilayer body.

5. The inductor array chip according to claim 1,
wherein respective positions of the plurality of coiled conductors in a lamination direction are different between at least two of the plurality of inductors.

6. A DC-to-DC converter module comprising:
a multilayer body formed by laminating a plurality of ceramic sheets, wherein at least some of the plurality of ceramic sheets have magnetism;
a plurality of inductors provided in the multilayer body; and
a switching IC mounted on the multilayer body and connected to the plurality of inductors,
wherein each of the plurality of inductors includes:
a plurality of coiled conductors provided between the plurality of ceramic sheets, wherein each of the plurality of inductors has a same number of the plurality of coiled conductors;
a first via hole conductor spirally connecting the plurality of coiled conductors; and
a second via hole conductor additionally connecting at least two coiled conductors of the plurality of coiled conductors located close to an outermost layer of the multilayer body, and connecting a part of the at least two coiled conductors in parallel or in a short-circuit manner, and
at least one of the plurality of inductors has an inductance value different from inductance values of other inductors.

7. The DC-to-DC converter module according to claim 6,
wherein the second via hole conductor is provided at a position different from starting end positions and terminating end positions of the coiled conductors.

8. The DC-to-DC converter module according to claim 6,
wherein the first via hole conductor is provided at a position different from the second via hole conductor.

9. The DC-to-DC converter module according to claim 6,
wherein the second via hole conductors are provided at each of a position close to one outermost layer of the multilayer body and a position close to the other outermost layer of the multilayer body.

10. The DC-to-DC converter module according to claim 6,
wherein respective positions of the plurality of coiled conductors in a lamination direction are different between at least two of the plurality of inductors.
